(19) United States
(12) Patent Application Publication
(10) Pub. No.: US 2025/0024661 A1
(43) Pub. Date: Jan. 16, 2025

(54) SEMICONDUCTOR MEMORY DEVICE

(71) Applicant: Samsung Electronics Co., Ltd., Suwon-si (KR)

(72) Inventor: Yong Gun JUNG, Suwon-si (KR)

(73) Assignee: Samsung Electronics Co., Ltd., Suwon-si (KR)

(21) Appl. No.: 18/618,293

(22) Filed: Mar. 27, 2024

(30) Foreign Application Priority Data
Jul. 12, 2023 (KR) 10-2023-0090149

(51) Int. Cl. H10B 12/00

(52) U.S. Cl. CPC H10B 12/482; H10B 12/315; H10B 12/485; H10B 12/488

(57) ABSTRACT

A semiconductor memory device includes a substrate including a first semiconductor film, a buried insulating film, and a second semiconductor film, which are sequentially stacked; bitlines within the buried insulating film and extending in a first direction; a device isolation film in the substrate and defining cell active regions, which extend in a second direction; and bitline contacts connecting the cell active regions and the bitlines, wherein the second direction intersects the first direction at an acute angle.

### CROSS-REFERENCE TO RELATED APPLICATION

This application claims priority from Korean Patent Application No. 10-2023-0090149 filed on Jul. 12, 2023 in the Korean Intellectual Property Office, and all the benefits accruing therefrom under 35 U.S.C. 119, the contents of which in its entirety are herein incorporated by reference.

### BACKGROUND

Various example embodiments relate to a semiconductor memory device.

As semiconductor devices become highly integrated, individual circuit patterns are becoming more finely detailed to realize a greater number of semiconductor devices within the same area. For example, as the integration density of semiconductor devices increases, the design rules for their components are being reduced.

As semiconductor devices shrink in size, the process of forming multiple buried contacts (BCs) between multiple wiring lines and the layers between them is becoming progressively more complex and challenging.

### SUMMARY

Aspects of various example embodiments may provide a semiconductor memory device with an improved product reliability.

However, aspects of inventive concepts are not restricted to those set forth herein. The above and other aspects will become more apparent to one of ordinary skill in the art to which example embodiments pertains by referencing the detailed description.

According to various example embodiments, there is provided a semiconductor memory device including a substrate including a first semiconductor film, a buried insulating film, and a second semiconductor film, which are sequentially stacked; bitlines within the buried insulating film and extending in a first direction; a device isolation film in the substrate defining cell active regions, the bit lines extending in a second direction; and bitline contacts connecting the cell active regions and the bitlines, wherein the second direction forms an acute angle with the first direction.

Alternatively or additionally according to various example embodiments, there is provided a semiconductor memory device including a substrate including a first semiconductor film, a buried insulating film, and a second semiconductor film, which are sequentially stacked; wordlines within the substrate and extending in a first direction; bitlines within the substrate and extending in a second direction; and a device isolation film in the substrate defining cell active regions, which extend in a third direction. The first, second, and third directions are different directions

Alternatively or additionally according to various example embodiments, there is provided a semiconductor memory device including a substrate including a cell area and a peripheral area; wordlines extending in a first direction on the cell area; bitlines extending in a second direction, which intersects the first direction, on the cell area; a device isolation film defining cell active regions, which extend in a third direction between the first and second directions, and a peripheral active region, which is on the peripheral area; and a peripheral wordline on the peripheral active region, wherein the wordlines and the bitlines are disposed within the substrate, the peripheral wordline is disposed on the substrate, and the substrate includes a first semiconductor film, a buried insulating film, and a second semiconductor film, which are sequentially stacked.

It should be noted that the effects are not limited to those described above, and other effects of example embodiments will be apparent from the following description.

### BRIEF DESCRIPTION OF THE DRAWINGS

The above and other aspects and features of the present disclosure will become more apparent by describing in detail various example embodiments thereof with reference to the attached drawings, in which:

FIG. 1 is a layout view of a semiconductor memory device according to some example embodiments;

FIG. 2 is a partial layout view illustrating cell and peripheral areas of FIG. 1;

FIG. 3 is a cross-sectional view taken along line A-A′ of FIG. 2;

FIG. 4 is a cross-sectional view taken along line B-B′ of FIG. 2;

FIG. 5 is a cross-sectional view taken along line C-C′ of FIG. 2;

FIG. 6 is a cross-sectional view taken along line D-D′ of FIG. 2;

FIG. 7 is a cross-sectional view taken along line E-E′ of FIG. 2;

FIG. 8 is a cross-sectional view taken along line F-F′ of FIG. 2;

FIG. 9 is a cross-sectional view of a semiconductor memory device according to some example embodiments;

FIGS. 10 through 13 are cross-sectional views of semiconductor memory devices according to some example embodiments;

FIGS. 14 through 22 are cross-sectional or layout views illustrating intermediate steps of a method of fabricating a semiconductor memory device according to some example embodiments;

FIGS. 23 through 31 are cross-sectional or layout views illustrating intermediate steps of a method of fabricating a semiconductor memory device according to some example embodiments; and

FIG. 32 depicts cross-sectional views illustrating intermediate steps of a method of fabricating a semiconductor memory device according to some example embodiments.

### DETAILED DESCRIPTION

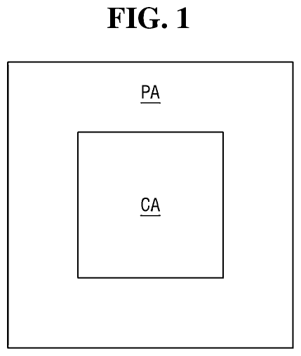

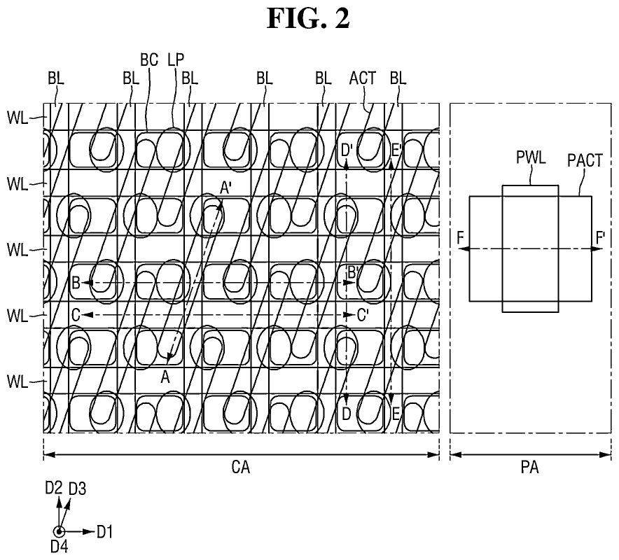

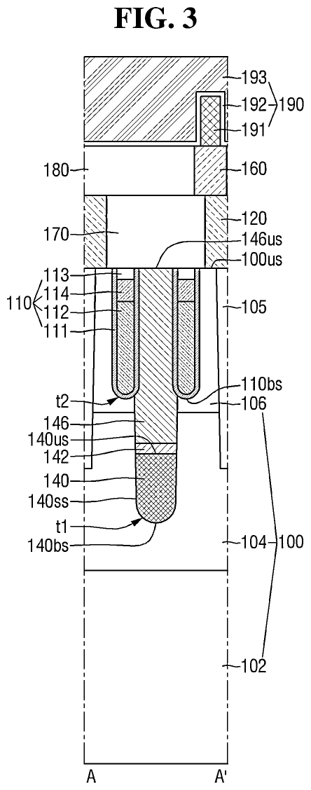

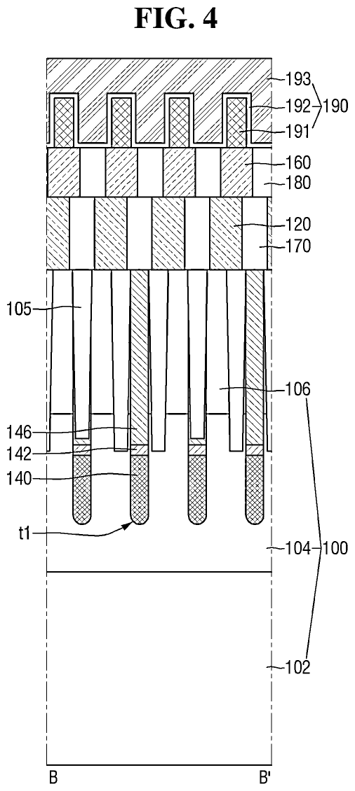

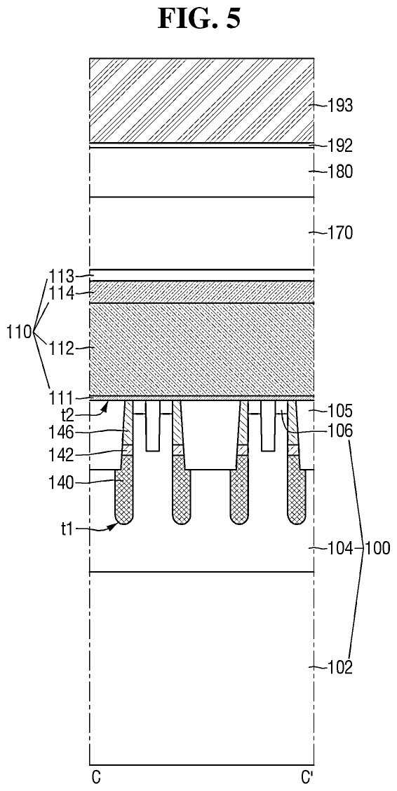

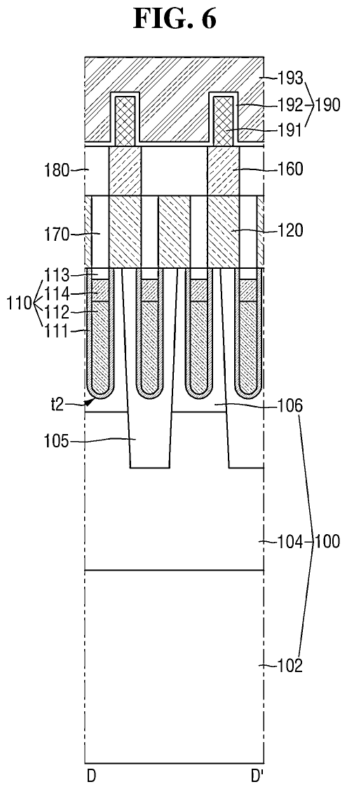

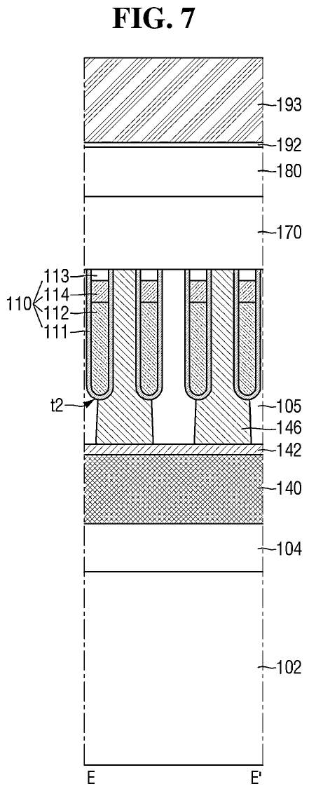

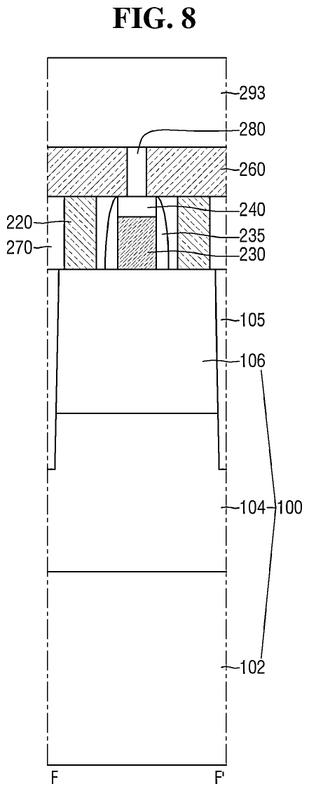

FIG. 1 is a layout view of a semiconductor memory device according to some example embodiments. FIG. 2 is a partial layout view illustrating cell and peripheral regions of FIG. 1. FIG. 3 is a cross-sectional view taken along line A-A′ of FIG. 2. FIG. 4 is a cross-sectional view taken along line B-B′ of FIG. 2. FIG. 5 is a cross-sectional view taken along line C-C′ of FIG. 2. FIG. 6 is a cross-sectional view taken along line D-D′ of FIG. 2. FIG. 7 is a cross-sectional view taken along line E-E′ of FIG. 2. FIG. 8 is a cross-sectional view taken along line F-F′ of FIG. 2.

The semiconductor memory device according to some example embodiments is illustrated as being a dynamic random access memory (DRAM) device, but example embodiments are not limited thereto.

Referring to FIGS. 1 and 2, the semiconductor memory device according to some example embodiments may include a cell area CA and a peripheral area PA.

The peripheral area PA may be disposed around the cell area CA. For example, the peripheral area PA may surround or at least partly surround the cell area CA.

The cell area CA may include a plurality of cell active regions ACT. The cell active regions ACT may be defined by a device isolation film (“105” of FIGS. 3 through 8), which is formed within a substrate 100. As the design rules for the semiconductor memory device according to some example embodiments decease, the cell active regions ACT may be arranged as diagonal or oblique bars. For example, the cell active regions ACT may extend in a third direction D3.

A plurality of gate electrodes, which extend in a first direction D1, may be arranged across the cell active regions ACT. The gate electrodes may extend in parallel to one another. The gate electrodes may be or may correspond to, for example, rows or wordlines WL. The wordlines WL may be arranged at equal intervals. The width of the wordlines WL and/or the spacing between the wordlines WL and/or the pitch of neighboring worldlines WL may be determined based on design rules.

A plurality of columns or bitlines BL, which extend in a second direction D2, may be disposed on the wordlines WL. The second direction D2 may intersect the first direction D1. The bitlines BL may extend in parallel to one another. The bitlines BL may be arranged at equal intervals. The width of the bitlines BL and/or the spacing between the bitlines BL and/or the pitch of neighboring bitlines may be determined based on design rules.

The first, second, and third directions D1, D2, and D3 are different directions. The second direction D2 may be orthogonal to the first direction D1. The third direction D3 is a direction between the first and second directions D1 and D2. The third direction D3 forms or intersects at an acute angle with the first direction D1 and with the second direction D2.

The semiconductor memory device according to some example embodiments may include various contact arrays, which are formed on the cell active regions ACT. The contact arrays may include, for example, buried contacts BC, landing pads LP, and bitline contacts (“146” of FIGS. 3 through 8).

The bitline contacts 146 may refer to contacts that electrically connect the cell active regions ACT to the bitlines BL. The buried contacts BC may refer to contacts that connect the cell active regions ACT to lower electrodes (“191” of FIGS. 3 through 8) of memory structures such as capacitors. The contact area between the buried contacts BC and the cell active regions ACT may be small. Consequently, to increase the contact area with the cell active regions ACT and expand the contact area with the lower electrodes 191, the landing pads LP, which have conductivity, may be introduced.

The landing pads LP may be positioned between the cell active regions ACT and the buried contacts BC, or between the buried contacts BC and the lower electrodes 191. The landing pads LP may be positioned between the buried contacts BC and the lower electrodes 191. By increasing the contact area with the cell active regions ACT and with the lower electrodes 191 via the landing pads LP, the contact resistance between the cell active regions ACT and the electrodes 191 can be reduced. There may be an increase in signal margin with the reduction of contact resistance.

Each of the cell active regions ACT may be divided into three parts by a pair of wordlines WL extending in the first direction D1. Each of the cell active regions ACT may include a middle portion and end portions at both ends of the corresponding cell active region ACT. The bitline contacts 146 may connect the middle portions of the cell active regions ACT and the bitlines BL. The buried contacts BC may be disposed at their respective ends of the cell active regions ACT.

As the buried contacts BC are disposed at their respective ends of each of the cell active regions ACT, the landing pads LP may be disposed to overlap or at least partially overlap with the buried contacts BC near their respective ends of each of the cell active regions ACT. For example, the buried contacts BC may be disposed to overlap with the cell active regions ACT between the wordlines WL, which are adjacent to one another, and between the bitlines BL, which are adjacent to one another.

The wordlines WL may be formed to be buried in the substrate 100. The wordlines WL may be arranged across the cell active regions ACT between bit line contacts 146 or the buried contacts BC. Two wordlines WL may be arranged across one cell active region ACT. As the cell active regions ACT extend in the third direction D3, the wordlines WL may form an angle smaller than 90 degrees with the cell active regions ACT.

The buried contacts BC may be symmetrically arranged. The buried contacts BC may be arranged in rows along the first and second directions D1 and D2. The landing pads LP may be arranged in a zigzag pattern in the second direction D2, which corresponds to the extension direction of the bitlines BL. The landing pads LP may be positioned to overlap with the same side surface of their respective bitlines BL in the first direction D1, which corresponds to the extension direction of the wordlines WL.

The peripheral area PA may include a peripheral active region PACT. The peripheral active region PACT may be defined by the device isolation film 105, which is formed within the substrate 100. A peripheral wordline PWL may be disposed on the peripheral active region PACT. The peripheral wordline PWL may intersect the peripheral active region PACT. Referring to FIG. 2, the peripheral area PA may be or may correspond to the area that overlaps with at least part of the cell area CA in the second direction D2.

Referring to FIGS. 1 through 8, the semiconductor memory device according to some example embodiments may include the substrate 100, the device isolation film 105, the cell active regions ACT, cell conductive lines 140, barrier metal layers 142, bitline contacts 146, cell gate structures 110, storage contacts 120, storage pads 160, cell insulating films (170 and 180), an information storage structure 190, a peripheral gate electrode 230, a peripheral gate capping pattern 240, peripheral spacers 235, through plugs 220, contact pads 260, and peripheral insulating films (270, 280, and 293).

Here, the terms “top surface,” “bottom surface,” “upper,” and “lower” are defined with respect to a fourth direction D4. The fourth direction D4 is a direction orthogonal to a top surface 100us of the substrate 100. The first, second, and third directions D1, D2, and D3 are directions parallel to the top surface 100us of the substrate 100.

The substrate 100 includes a first semiconductor film 102, a buried insulating film 104, and a second semiconductor film 106, which are sequentially stacked.

The first semiconductor film 102 may include a base layer and an epitaxial layer, for example a layer that is grown on the base layer, but example embodiment are not limited thereto. The first semiconductor film 102 may include only a base substrate without an epitaxial layer. The first semiconductor film 102 may include a silicon (Si) substrate and/or a silicon-germanium (SiGe) substrate.

The buried insulating film 104 is disposed on the first semiconductor film 102. The buried insulating film 104 may cover the entire top surface of the first semiconductor film 102.

The buried insulating film 104 may include at least one of, for example, silicon oxide (SiO₂), silicon nitride (SiN), silicon oxynitride (SiON), and a combination thereof, but example embodiments are not limited thereto. In some example embodiments, the buried insulating film 104 may be or may include a buried oxide (BOX); example embodiments are not limited thereto.

The second semiconductor film 106 is disposed on the buried insulating film 104. The second semiconductor film 106 may cover the entire top surface of the buried insulating film 104.

The second semiconductor film 106 may include monocrystalline Si. For example, the substrate 100 may be a silicon-on-insulator (SOI) substrate. The use of monocrystalline Si, which has low resistivity and has high carrier mobility may lead to improved characteristics of the semiconductor memory device according to various example embodiments.

Here, the term “monocrystalline” may refer to a state where no grain boundaries exist and the orientation of crystals remains consistent. However, the term “monocrystalline may also encompass layers or parts that are virtually monocrystalline, even if there are localized grain boundaries or regions with different crystal orientations, it virtually signifies that the layer or portion is considered monocrystalline. As an example, a substantially monocrystalline layer may include multiple low-angle grain boundaries.

The device isolation film 105 may be formed within the substrate 100. The device isolation film 105 may have a shallow trench isolation (STI) structure with excellent device isolation characteristics. The device isolation film 105 may define the cell active regions ACT in the cell area CA.

Referring to FIG. 2, the cell active regions ACT, which are defined by the device isolation film 105, may have a long island shape with short and long axes. The cell active regions ACT may have a diagonal line shape, forming an angle smaller than 90 degrees with the wordlines WL, which are formed within the device isolation film 105. Also, the cell active regions ACT may have a diagonal line shape, forming an angle smaller than 90 degrees with the bitlines BL, which are formed on the device isolation film 105.

The bottom surface of the device isolation film 105 may be positioned within the buried insulating film 104. The cell active regions ACT may be defined in the second semiconductor film 106.

The device isolation film 105 may include at least one of, for example, a silicon oxide film, a silicon nitride film, and a silicon oxynitride film, but example embodiments are not limited thereto. In some example embodiments, the device isolation film 105 may be a shallow-trench isolation (STI) film; example embodiments are not limited thereto.

The device isolation film 105 is illustrated as being formed as a single insulating film, but example embodiments are not limited thereto. The device isolation film 105 may be formed as a single insulating film or as a stack of multiple insulating films, depending on the spacing between the cell active regions ACT.

The cell gate structures 110 are disposed on the cell area CA. The cell gate structures 110 are formed within the substrate 100 and the device isolation film 105. The cell gate structures 110 are disposed within the second semiconductor film 106. Bottom surfaces 110bs of the cell gate structures 110 are disposed within the second semiconductor film 106.

For example, the bottom surfaces 110bs of the cell gate structures 110 may be positioned lower within the device isolation film 105 than within the cell active regions ACT, specifically, within the second semiconductor film 106. The bottom surfaces 110bs of the cell gate structures 110 may be curved.

The cell gate structures 110 may include, for example, cell gate insulating films 111, cell gate electrodes 112, cell gate capping patterns 113, and cell gate capping conductive films 114. Alternatively or additionally, in some example embodiments, the cell gate structures 110 may not include the cell gate capping conductive films 114.

The cell gate electrodes 112 may correspond to wordlines WL. For example, the cell gate electrodes 112 may correspond to the wordlines WL of FIG. 2. The bottom surfaces of the cell gate electrodes 112 may be positioned within the second semiconductor film 106.

The substrate 100 includes or defines second trenches t2. The bottom surfaces of the second trenches t2 are positioned within the second semiconductor film 106. The cell gate insulating films 111 may extend along the sidewalls and bottom surfaces of the second trenches t2. The bottom surfaces of the second trenches t2 may correspond to the bottom surfaces 110bs of the cell gate structures 110. The cell gate insulating films 111 may extend wholly or at least partially along the profiles of the second trenches t2.

The cell gate insulating films 111 may include at least one of, for example, silicon oxide, silicon nitride, silicon oxynitride, or a high-k material with a greater dielectric constant than that of silicon oxide.

The cell gate electrodes 112 may be disposed on the cell gate insulating films 111. The cell gate electrodes 112 may partially fill the second trenches t2. The cell gate capping conductive films 114 may extend along the top surfaces of the cell gate electrodes 112.

The cell gate electrodes 112 may include at least one of a metal, a metal alloy, a conductive metal nitride, a conductive metal carbonitride, a conductive metal carbide, a metal silicide, a doped semiconductor material, a conductive metal oxynitride, and a conductive metal oxide.

The cell gate capping conductive films 114 may include one or more of, for example, polysilicon such as doped polysilicon, polysilicon-germanium such as doped polysilicon-germanium, amorphous silicon, and amorphous silicon-germanium, but example embodiments are not limited thereto.

The cell gate capping patterns 113 may be disposed on the cell gate electrodes 112 and the cell gate capping conductive films 114. The cell gate capping patterns 113 may fill portions of the second trenches t2 that remain empty after the formation of the cell gate electrodes 112 and the cell gate capping conductive films 114. The cell gate insulating films 111 may extend along, for example, the sidewalls of the cell gate capping patterns 113. Alternatively, the cell gate insulating films 111 may not extend along, for example, the sidewalls of the cell gate capping patterns 113.

The cell gate capping patterns 113 may include at least one of, for example, SiN, SiON, SiO₂, SiCN, SiOCN, and a combination thereof.

Impurity-doped regions may be formed on at least one side of each of the cell gate structures 110. The impurity-doped regions may correspond to the source/drain regions of transistors, and may include, for example, at least one of boron, arsenic, or phosphorus. The impurity-doped regions may be formed at both ends of the cell active regions ACT.

The substrate 100 includes first trenches t1. In some example embodiments, the first trenches t1 may extend from the top surface 100us of the substrate 100 into the substrate 100. The top surface 100us of the substrate 100 corresponds to the top surface of the second semiconductor film 106. The bottom surfaces of the first trenches t1 may be positioned within the buried insulating film 104.

The cell conductive lines 140 are disposed within the substrate 100. The cell conductive lines 140 are disposed within the buried insulating film 104. The cell conductive lines 140 are disposed within the first trenches t1. The bottom surfaces of the first trenches t1 may correspond to bottom surfaces 140bs of the cell conductive lines 140. The bottom surfaces 140bs of the cell conductive lines 140 are disposed within the buried insulating film 104. The bottom surfaces 140bs of the cell conductive lines 140 may be positioned below the bottom surfaces 110bs of the cell gate structures 110 and the bottom surfaces of the cell gate electrodes 112. Top surfaces 140us of the cell conductive lines 140 are disposed within the buried insulating film 104. The bottom surfaces 140bs and side surfaces 140ss of the cell conductive lines 140 may be surrounded by the buried insulating film 104. The bottom surfaces 140bs and the side surfaces 140ss of the cell conductive lines 140 may be in contact with the buried insulating film 104.

Here, the cell conductive lines 140 may correspond to bitlines BL. For example, the cell conductive lines 140 may correspond to the bitlines BL of FIG. 2.

The cell conductive lines 140 may include at least one of, an impurity-doped semiconductor material, a conductive silicide compound, a conductive metal nitride, a two-dimensional (2D) material, a metal, and a metal alloy.

For example, the cell conductive lines 140 may be single films. For example, the cell conductive lines 140 may be multifilms including stacks of multiple conductive films.

The barrier metal layers 142 may extend along the top surfaces of the cell conductive lines 140. The barrier metal layers 142 may be disposed within the buried insulating film 104. The barrier metal layers 142 may include at least one of, for example, an impurity-doped semiconductor material, a conductive silicide compound, a conductive metal nitride, a metal, and a metal alloy.

The bitline contacts 146 are disposed within the substrate 100. The bitline contacts 146 are disposed on the cell conductive lines 140. The bitline contacts 146 may fill portions of the first trenches t1 that remain empty after the formation of the cell conductive lines 140 and the barrier metal layers 142. The bottom surfaces of the bitline contacts 146 are disposed within the buried insulating film 104.

At least parts of the bitline contacts 146 may be in contact with the second semiconductor film 106. In some example embodiments, top surfaces 146us of the bitline contacts 146 may be disposed above the interface between the buried insulating film 104 and the second semiconductor film 106. The top surfaces 146us of the bitline contacts 146 may be disposed above the bottom surfaces 110bs of the cell gate structures 110. The top surfaces 146us of the bitline contacts 146 may be in contact with a first cell insulating film 170.

The bitline contacts 146 electrically connect the cell conductive lines 140 and the substrate 100 (e.g., the second semiconductor film 106). In some example embodiments, the bitline contacts 146 may be formed over the entire cell active regions ACT that overlap with the cell conductive lines 140 in the fourth direction D4.

The bitline contacts 146 may include at least one of, an impurity-doped semiconductor material, a conductive metal silicide, a conductive metal nitride, a conductive metal oxide, a metal, and a metal alloy.

The storage contacts 120 may be disposed between cell conductive lines 140 that are adjacent to one another in the first direction D1. The storage contacts 120 may be disposed on both sides of the cell conductive lines 140. The storage contacts 120 may be disposed between the cell conductive lines 140.

The storage contacts 120 may overlap with the substrate 100 and the device isolation film 105 between the cell conductive lines 140. The storage contacts 120 may be connected to both ends of the cell active regions ACT.

Here, the storage contacts 120 may correspond to the buried contacts BC of FIG. 2.

The storage contacts 120 may include one of, for example, an impurity-doped semiconductor material, a conductive silicide compound, a conductive metal nitride, and a metal.

The storage pads 160 may be disposed on their respective storage contacts 120. The storage pads 160 may be electrically connected to the storage contacts 120. The storage pads 160 may be connected to both ends of the cell active regions ACT.

Here, the storage pads 160 may correspond to the landing pads LP of FIG. 2.

The storage pads 160 may partially overlap with the top surfaces of the cell conductive lines 140. The storage pads 160 may include at least one of, for example, an impurity-doped semiconductor material, a conductive silicide compound, a conductive metal nitride, a conductive metal carbide, a metal, and a metal alloy.

The storage contacts 120 and the storage pads 160 may be disposed within the cell insulating films (170 and 180). For example, the first cell insulating film 170 may cover the top surface 100us of the substrate 100. The storage contacts 120 may be disposed within the first cell insulating film 170. A second cell insulating film 180 may be disposed on the first cell insulating film 170. The storage pads 160 may be disposed within the second cell insulating film 180.

For example, the first and second cell insulating films 170 and 180 may include at least one of silicon oxide, silicon nitride, silicon oxynitride, silicon oxycarbonitride, and silicon carbonitride, but example embodiments are not limited thereto.

The information storage structure 190 may be disposed on the storage pads 160. The information storage structure 190 is connected to the storage pads 160. For example, one cell insulating film may be disposed between the information storage structure 190 and the substrate 100, and one contact may be disposed within the cell insulating film.

The information storage structure 190 may include, for example, memristors and/or capacitors. The information storage structure 190 may include the lower electrodes 191, a dielectric film such as a capacitor dielectric film 192, and an upper electrode 193.

For example, the upper electrode 193 may be a plate upper electrode having a plate shape. The lower electrodes 191 may be disposed on the storage pads 160. The lower electrodes 191 may have, for example, a pillar shape; however, example embodiments are not limited thereto.

The capacitor dielectric film 192 is formed on the lower electrodes 191. The capacitor dielectric film 192 may be formed along the profiles of the lower electrodes 191. The upper electrode 193 is formed on the capacitor dielectric film 192. The upper electrode 193 may surround the outer sidewalls of the lower electrodes 191. The upper electrode 193 is illustrated as being a single film, but example embodiments are not limited thereto.

The lower electrodes 191 and the upper electrode 193 may include, for example, one or more of a doped semiconductor material, a conductive metal nitride (e.g., one or more of titanium nitride, tantalum nitride, niobium nitride, or tungsten nitride), a metal (e.g., one or more of ruthenium, iridium, titanium, or tantalum), or a conductive metal oxide (e.g., iridium oxide and/or niobium oxide), but example embodiments are not limited thereto.

The capacitor dielectric film 192 may include one of, for example, silicon oxide, silicon nitride, silicon oxynitride, a high-k material, and a combination thereof, but example embodiments are not limited thereto.

The peripheral gate electrode 230 is disposed on the peripheral area PA. The peripheral gate electrode 230 is disposed on the peripheral active region PACT, which is defined by the device isolation film 105. The peripheral gate electrode 230 is disposed on the substrate 100. The peripheral gate electrode 230 is disposed on the second semiconductor film 106.

Here, the peripheral gate electrode 230 may correspond to a peripheral wordline PWL.

The peripheral gate electrode 230 may include at least one of, for example, an impurity-doped semiconductor material, a conductive silicide compound, a conductive metal nitride, a 2D material, a metal, and a metal alloy. The peripheral gate electrode 230 may be, for example, a single film. Alternatively, the peripheral gate electrode 230 may be a multifilm including a stack of multiple conductive films.

The peripheral gate capping pattern 240 may be disposed on the peripheral gate electrode 230. The peripheral spacers 235 may be disposed on the sidewalls of the peripheral gate electrode 230 and the sidewalls of the peripheral gate capping pattern 240. A peripheral dielectric film may be further disposed between the substrate 100 and the peripheral gate electrode 230.

The peripheral spacers 235 may include at least one of, for example, silicon nitride, silicon oxynitride, silicon oxide, silicon carbonitride, silicon oxycarbonitride, and a combination thereof. The peripheral gate capping pattern 240 may include at least one of, for example, silicon nitride, silicon oxynitride, and silicon oxide.

The through plugs 220 may be disposed on both sides of the peripheral gate electrode 230. The through plugs 220 may penetrate a first peripheral insulating film 270 and may extend to the substrate 100 in the peripheral area PA. The through plugs 220 are connected to the substrate 100 in the peripheral area PA. The contact pads 260 are disposed on the through plugs 220. The contact pads 260 are connected to the through plugs 220. The through plugs 220 are disposed within the second peripheral insulating film 280. The through plugs 220 and the contact pads 260 may be connected without any physical boundaries therebetween.

A third peripheral insulating film 293 may cover the sidewalls of the upper electrode 193. The third peripheral insulating film 293 may include an insulating material.

As the size of the semiconductor memory device according to some example embodiments decreases, the available space for forming the buried contact BC is diminished. As a result, the distance between the buried contacts BC and the bitlines BL in a horizontal direction (e.g., in the first direction D1) may decrease, and the parasitic capacitance between the buried contacts BC and the bitlines BL may increase.

However, in the semiconductor memory device according to some example embodiments, the bitlines BL and the bitline contacts 146 are disposed within the substrate 100, and the buried contacts BC are disposed on the substrate 100. As a result, there is ample space available for the formation of the buried contacts BC, and the distance between the bitline contacts 146 and the buried contacts BC can be adequately maintained. Additionally, in the semiconductor memory device according to some example embodiments, the bitlines BL are disposed within the buried insulating film 104 of the substrate 100, and there are no other conductive patterns positioned at the same height as the bitlines BL. Consequently, the absence of nearby conductive patterns around the bitlines BL can reduce the parasitic capacitance between the bitlines BL and conductive patterns.

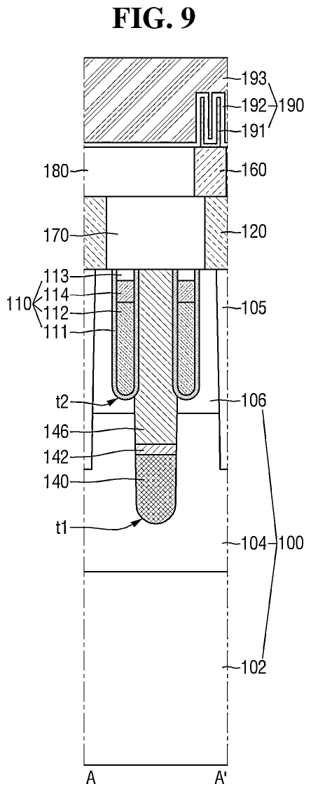

FIG. 9 is a cross-sectional view of a semiconductor memory device according to some example embodiments. Specifically, FIG. 9 is a cross-sectional view taken along line A-A′ of FIG.

2. For convenience, the embodiment of FIG. 9 will hereinafter be described, highlighting the differences with the embodiment of FIGS. 1 through 8.

Referring to FIG. 9, lower electrodes 191 may have a cylindrical shape.

Each of the lower electrodes 191 may include a bottom portion, which extends along the top surface of a storage pad 160, and sidewall portions, which extend from the bottom portion in a fourth direction D4.

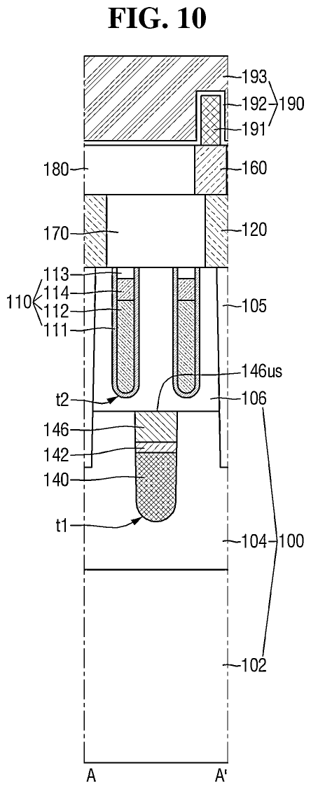

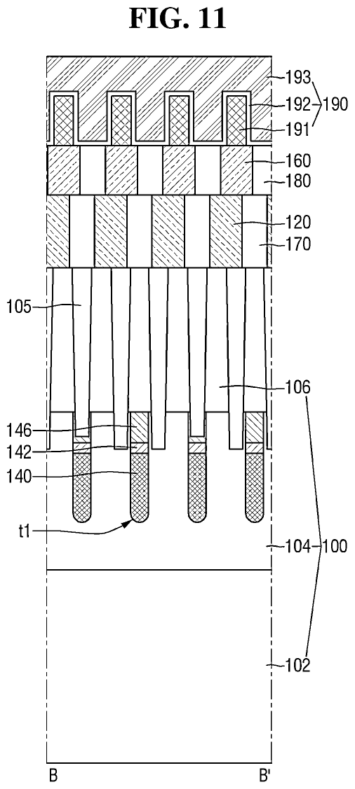

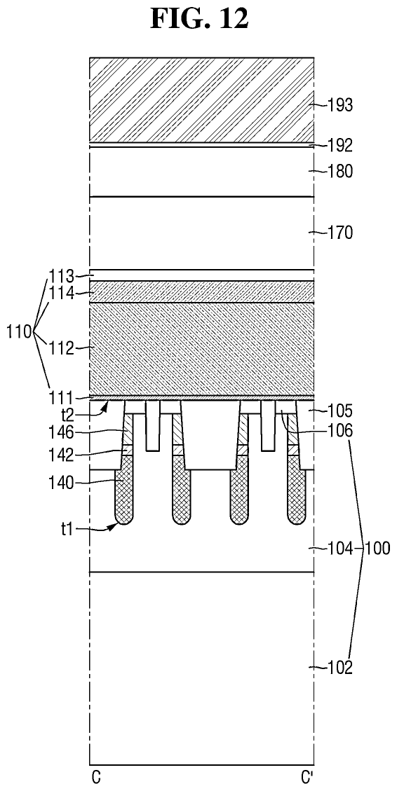

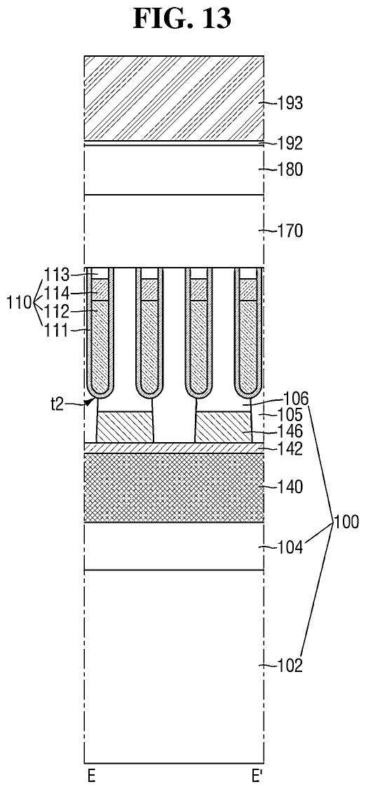

FIGS. 10 through 13 are cross-sectional views of semiconductor memory devices according to some example embodiments. Specifically, FIG. 10 is a cross-sectional view taken along line A-A′ of FIG. 2, FIG. 11 is a cross-sectional view taken along line B-B′ of FIG. 2, FIG. 12 is a cross-sectional view taken along line C-C′ of FIG. 2, and FIG. 13 is a cross-sectional view taken along line E-E′ of FIG. 2. For convenience, the embodiments of FIGS. 10 through 13 will hereinafter be described, highlighting the differences with the embodiment of FIGS. 1 through 8.

Referring to FIGS. 10 through 13, bitline contacts 146 may be disposed between cell conductive lines 140 and cell active regions ACT. Top surfaces 146us of the bitline contacts 146 may be disposed below bottom surfaces 110bs of cell gate structures 110. The top surfaces 146us of the bitline contacts 146 may be in contact with a second semiconductor film 106. The bitline contacts 146 may be disposed within a buried insulating film 104.

In some example embodiments, interfaces may exist between the bitline contacts 146 and the second semiconductor film 106. Alternatively, in some example embodiments, the bitline contacts 146 and the second semiconductor film 106 may be connected without any interfaces therebetween.

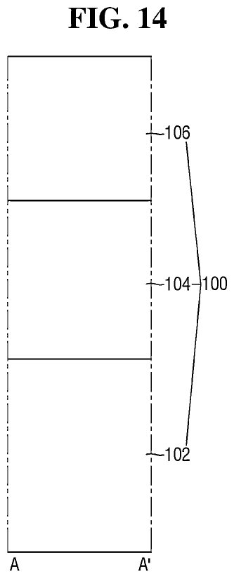

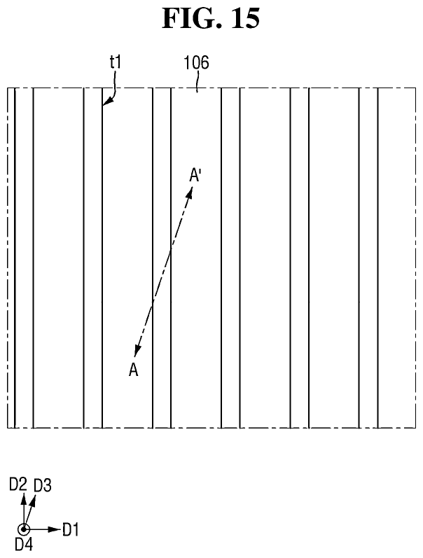

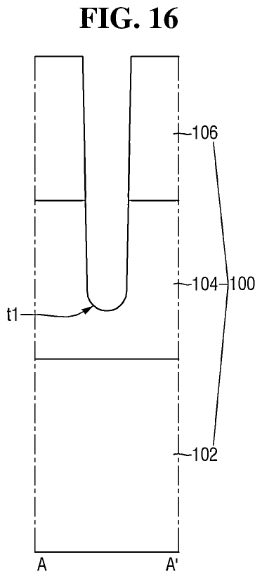

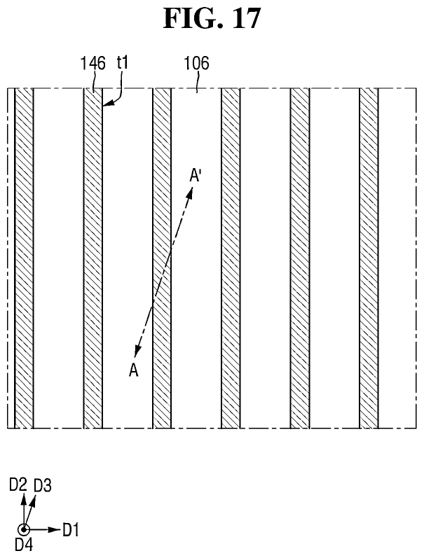

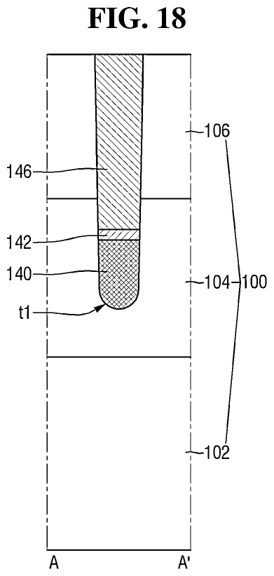

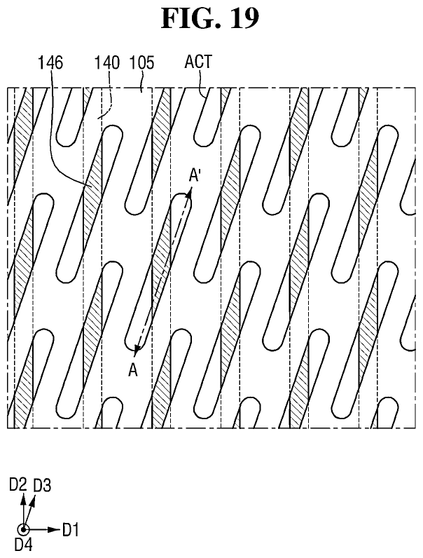

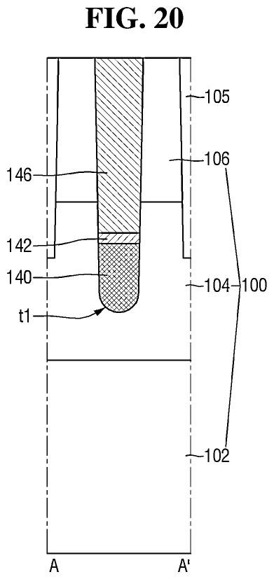

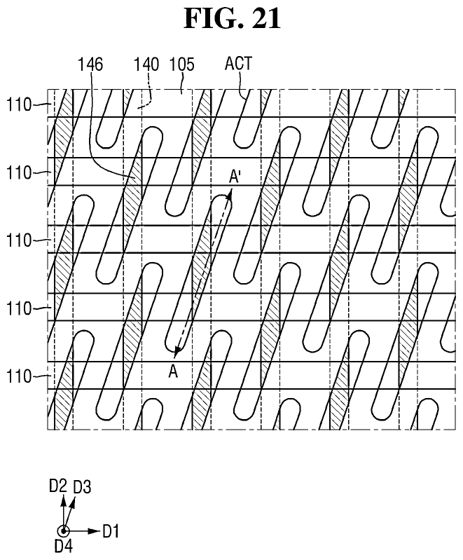

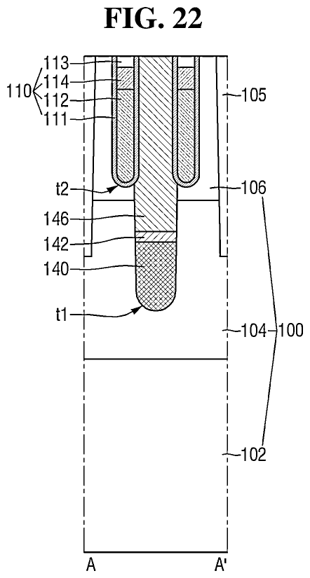

FIGS. 14 through 22 are cross-sectional views illustrating intermediate steps of a method of fabricating a semiconductor memory device according to some example embodiments. Specifically, FIG. 16 is a cross-sectional view taken along line A-A′ of FIG. 15, FIG. 18 is a cross-sectional view taken along line B-B′ of FIG. 17, FIG. 20 is a cross-sectional view taken along line A-A′ of FIG. 19, and FIG. 22 is a cross-sectional view taken along line A-A′ of FIG. 21. For convenience, the embodiments of FIGS. 14 through 22 will hereinafter be described, highlighting the differences with the embodiment of FIGS. 1 through 8.

Referring to FIG. 14, a substrate 100 is provided. The substrate 100 includes a first semiconductor film 102, a buried insulating film 104, and a second semiconductor film 106, which are sequentially stacked.

Referring to FIGS. 15 and 16, first trenches t1 are formed within the substrate 100. The first trenches t1 extend in a second direction D2. The first trenches t1 are arranged in a first direction D1.

The first trenches t1 extend from the top surface of the substrate 100 into the substrate 100. The bottom surfaces of the first trenches t1 may be disposed within the buried insulating film 104.

Referring to FIGS. 17 and 18, cell conductive lines 140 are formed within the first trenches t1. The cell conductive lines 140 partially fill the first trenches t1. The top surfaces of the cell conductive lines 140 are disposed within the buried insulating film 104. Consequently, bitlines BL are formed within the buried insulating film 104.

Barrier metal layers 142 are formed on the cell conductive lines 140 in the first trenches t1. The top surfaces of the barrier metal layers 142 may be disposed within the buried insulating film 104. Bitline contacts 146 are formed on the barrier metal layers 142 in the first trenches t1. The bitline contacts 146 may fill portions of the first trenches t1 that remain empty after the formation of the cell conductive lines 140 and the barrier metal layers 142. As a result, the bitline contacts 146 are formed within the substrate 100.

Referring to FIGS. 19 and 20, a device isolation film 105 may be formed within the substrate 100, and as a result, cell active regions ACT may be formed. The bitline contacts 146 may connect the middle portions of the cell active regions ACT and the bitlines BL.

For example, the device isolation film 105 may be formed in both a cell area CA and a peripheral area PA at the same time, and as a result, the cell active regions ACT and a peripheral active region PACT may be formed at the same time.

Referring to FIGS. 21 and 22, second trenches t2 are formed within the substrate 100. The second trenches t2 extend in the first direction D1 and are arranged in the second direction D2. The second trenches t2 extend from the top surface of the substrate 100 into the substrate 100. The bottom surfaces of the first trenches t1 are disposed within the second semiconductor film 106.

Cell gate structures 110 are formed in the second trenches t2. The cell gate structures 110 are formed within the second semiconductor film 106. Consequently, wordlines WL are formed within the second semiconductor film 106.

Thereafter, referring again to FIG. 3, storage contacts 120 are formed on the substrate 100. Storage pads 160 are formed on the storage contacts 120. An information storage structure 190 is formed on the storage pads 160.

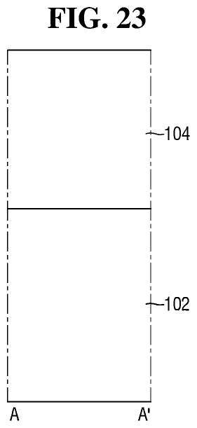

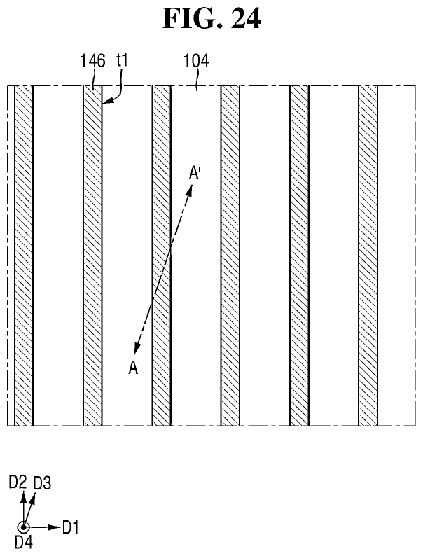

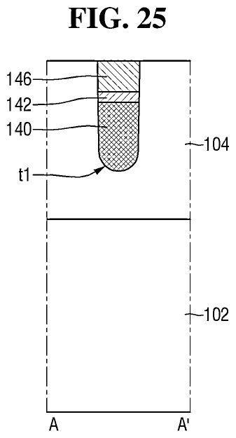

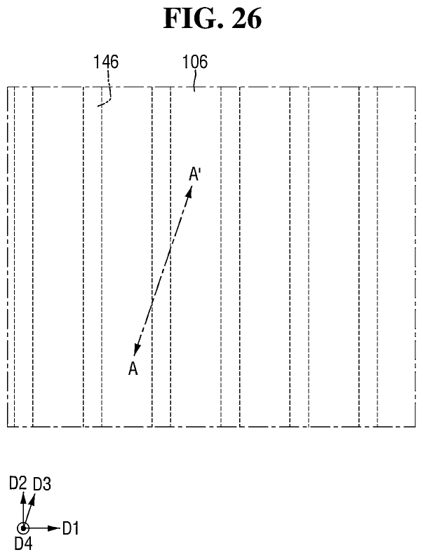

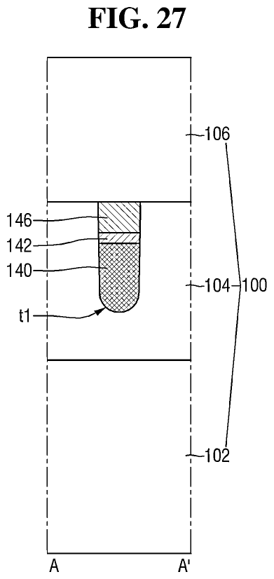

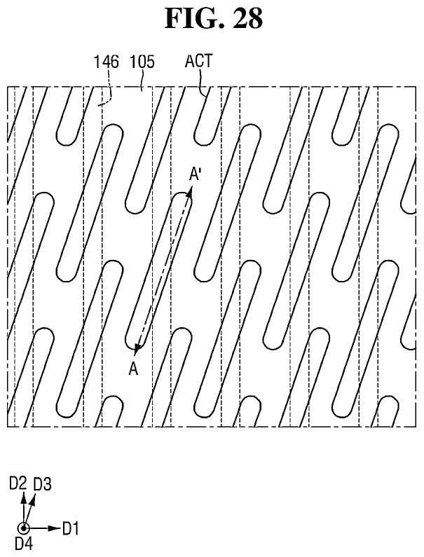

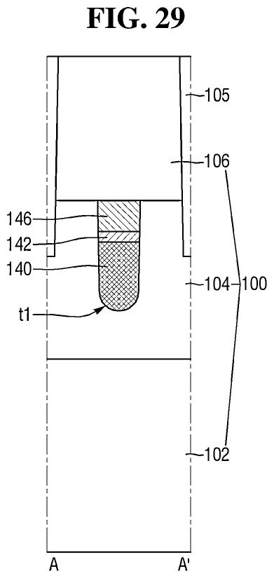

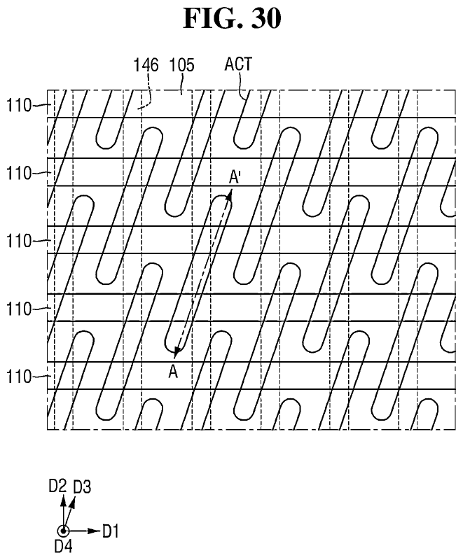

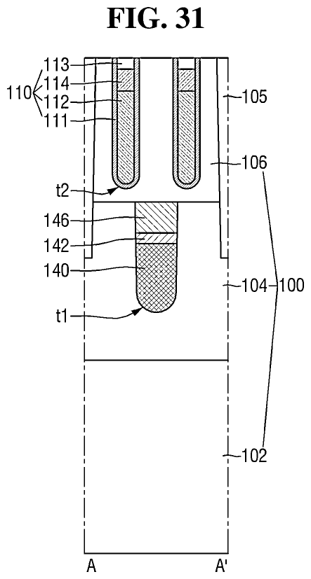

FIGS. 23 through 31 are cross-sectional or layout views illustrating intermediate steps of a method of fabricating a semiconductor memory device according to some example embodiments. Specifically, FIG. 25 is a cross-sectional view taken along line A-A′ of FIG. 24, FIG. 27 is a cross-sectional view taken along line A-A′ of FIG. 26, FIG. 29 is a cross-sectional view taken along line A-A′ of FIG. 28, and FIG. 31 is a cross-sectional view taken along line A-A′ of FIG. 30. For convenience, the embodiments of FIGS. 23 through 31 will hereinafter be described, highlighting the differences with the embodiment of FIGS. 10 through 22.

Referring to FIG. 23, a first semiconductor film 102 is provided. For example, the first semiconductor film 102 may be a Si substrate. In some example embodiments, the first semiconductor film 102 may not be a silicon-on-insulator film.

A buried insulating film 104 is formed on the first semiconductor film 102. The buried insulating film 104 may cover the top surface of the first semiconductor film 102.

Referring to FIGS. 24 and 25, first trenches t1 are formed within the buried insulating film 104. The first trenches t1 may extend from the top surface of the buried insulating film 104 into the buried insulating film 104.

Bitline contacts 146 may fill portions of the first trenches t1 that remain empty after the formation of cell conductive lines 140 and barrier metal layers 1421. Consequently, bitlines Bl and the bitline contacts 146 are formed within the buried insulating film 104.

Referring to FIGS. 26 and 27, a second semiconductor film 106 is formed on the buried insulating film 104. The second semiconductor film 106 may be formed by an epitaxial growth process using the bitline contacts 146. The second semiconductor film 106 may be an epitaxial Si film. As a result, no interfaces may exist between the bitline contacts 146 and the second semiconductor film 106.

Referring to FIGS. 28 and 29, a device isolation film 105 may be formed within a substrate 100, and as a result, cell active regions ACT may be formed.

Referring to FIGS. 30 and 31, second trenches t2 are formed within the substrate 100. Cell gate structures 110 are formed in the second trenches t2. As a result, wordlines WL are formed within the second semiconductor film 106.

Thereafter, referring again to FIG. 10, storage contacts 120 are formed on the substrate 100. Storage pads 160 are formed on the storage contacts 120. An information storage structure 190 is formed on the storage pads 160.

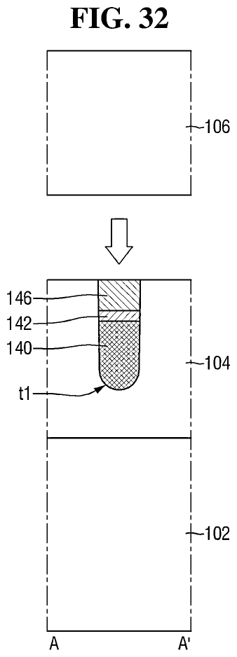

FIG. 32 depicts cross-sectional views illustrating intermediate steps of a method of fabricating a semiconductor memory device according to some example embodiments. The steps depicted in FIG. 32 may be steps to be performed after those depicted in FIG. 25. After the processing depicted in FIG. 32, the processing depicted in FIGS. 28 through 31 may be performed. Therefore, explanations that overlap with the content already described in FIGS. 23 and 24 will be simplified or omitted.

Referring to FIG. 32, a second semiconductor film 106 is provided. For example, the second semiconductor film 106 may be a Si substrate. A buried insulating film 104 and the second semiconductor film 106 may be bonded together. Consequently, a substrate 100, which includes a first semiconductor film 102, a buried insulating film 104, and the second semiconductor film 106 that are sequentially stacked, may be formed.

Various example embodiments have been described with reference to the accompanying drawings. However, it should be understood that inventive concepts are not limited to these embodiments and can be implemented in various other forms. Those of ordinary skill in the art to which example embodiments pertains, with ordinary knowledge in the field, will understand that the technical concepts and/or essential features of inventive concepts can be implemented in different specific forms without altering their essence. Therefore, embodiments described above should be considered as examples only and not restrictive in any way. Additionally example embodiments are not necessarily mutually exclusive. For example, some example embodiments may include one or more features described with reference to one or more figures, and may also include one or more other features described with reference to one or more other figures.

What is claimed is:

1. A semiconductor memory device comprising:
a substrate including a first semiconductor film, a buried insulating film, and a second semiconductor film, which are sequentially stacked;
bitlines within the buried insulating film and extending in a first direction;
a device isolation film in the substrate and defining cell active regions, which extend in a second direction; and
bitline contacts connecting the cell active regions and the bitlines,
wherein the second direction intersects the first direction at an acute angle.

2. The semiconductor memory device of claim 1, wherein top surfaces of the bitlines are within the buried insulating film.

3. The semiconductor memory device of claim 1, wherein the second semiconductor film includes monocrystalline silicon.

4. The semiconductor memory device of claim 1, further comprising:
a cell insulating film on the substrate;
storage contacts on first and second sides of each of the bitlines within the cell insulating film, the storage contacts being connected to the cell active regions; and
an information storage structure on the storage contacts, the information storage structure connected to the storage contacts.

5. The semiconductor memory device of claim 4, wherein top surfaces of the bitline contacts are in contact with the cell insulating film.

6. The semiconductor memory device of claim 1, wherein top surfaces of the bitline contacts are in contact with the second semiconductor film.

7. The semiconductor memory device of claim 1, further comprising:
wordlines extending in a third direction within the substrate,
wherein the second direction intersects the third direction at an acute angle.

8. The semiconductor memory device of claim 7, wherein bottom surfaces of the wordlines are above bottom surfaces of the bitlines.

9. The semiconductor memory device of claim 1, wherein a bottom surface of the device isolation film is above bottom surfaces of the bitlines.

10. A semiconductor memory device comprising:
a substrate including a first semiconductor film, a buried insulating film, and a second semiconductor film, which are sequentially stacked;
wordlines within the substrate and extending in a first direction;
bitlines within the substrate and extending in a second direction; and
a device isolation film defining cell active regions, which extend in a third direction, in the substrate,
wherein the first, second, and third directions are different directions.

11. The semiconductor memory device of claim 10, wherein
the second direction is orthogonal to the first direction, and
the third direction is a direction between the first and second directions.

12. The semiconductor memory device of claim 10, wherein bottom surfaces of the bitlines are within the buried insulating film.

13. The semiconductor memory device of claim 10, wherein top surfaces of the bitlines are within the buried insulating film.

14. The semiconductor memory device of claim 10, wherein the second semiconductor film includes monocrystalline silicon.

15. The semiconductor memory device of claim 10, wherein
the substrate defines a plurality of trenches, and
the semiconductor memory device further comprises bitline contacts,
the bitlines are in the trenches, and
the bitline contacts are on the bitlines, filling the trenches.

16. The semiconductor memory device of claim 10, wherein
the buried insulating film defines a plurality of trenches,
the semiconductor devices further comprises bitline contacts,
the bitlines are in the trenches, and
the bitline contacts are on the bitlines, filling the trenches.

17. The semiconductor memory device of claim 10, wherein bottom surfaces of the wordlines are disposed within the first semiconductor film.

18. A semiconductor memory device comprising:
a substrate including a cell area and a peripheral area;
wordlines on the cell area and extending in a first direction;
bitlines on the cell area and extending in a second direction, which intersects the first direction;
a device isolation film defining cell active regions, which extend in a third direction between the first and second directions, and a peripheral active region, which is on the peripheral area; and
a peripheral wordline on the peripheral active region, wherein
the wordlines and the bitlines are within the substrate,
the peripheral wordline is on the substrate, and
the substrate includes a first semiconductor film, a buried insulating film, and a second semiconductor film, which are sequentially stacked.

19. The semiconductor memory device of claim 18, wherein sidewalls and bottom surfaces of the bitlines are in contact with the buried insulating film.

20. The semiconductor memory device of claim 18, wherein the wordlines are within the second semiconductor film.
